(19) United States
(12) Patent Application Publication
(10) Pub. No.: US 2015/0166838 A1
(43) Pub. Date: Jun. 18, 2015

(54) POLISHING COMPOSITION, MANUFACTURING PROCESS THEREFOR, UNDILUTED LIQUID, PROCESS FOR PRODUCING SILICON SUBSTRATE, AND SILICON SUBSTRATE

(71) Applicant: FUJIMI INCORPORATED, Kiyosu-shi, Aichi (JP)

(72) Inventors: Kohsuke Tsuchiya, Kiyosu-shi (JP); Yoshio Mori, Kiyosu-shi (JP); Shuhei Takahashi, Kiyosu-shi (JP); Shinichiro Takami, Kiyosu-shi (JP)

(73) Assignee: FUJIMI INCORPORATED, Kiyosu-shi, Aichi (JP)

(21) Appl. No.: 14/372,148

(22) PCT Filed: Jan. 16, 2013
(86) PCT No.: PCT/JP2013/050627

§ 371 Date: Jul. 14, 2014

(30) Foreign Application Priority Data
Jan. 16, 2012 (JP) 2012-006372

(51) Int. Cl. C09G 1/02; C01B 33/02; B24B 37/04

(52) U.S. Cl. CPC C09G 1/02; B24B 37/044; C01B 33/02

(57) ABSTRACT

A polishing composition is obtained through diluting an undiluted liquid containing abrasive grains. When R1 is defined as an average secondary particle diameter of the abrasive grains in the undiluted liquid and R2 is defined as an average secondary particle diameter of the abrasive grains in the polishing composition, the ratio R2/R1 is 1.2 or less. The polishing composition is used for polishing a silicon substrate material to produce a silicon substrate.

### TECHNICAL FIELD

The present invention relates to a polishing composition, a method for producing the same, an undiluted liquid for preparing a polishing composition, a silicon substrate production method using the polishing composition, and a silicon substrate produced by using the polishing composition.

### BACKGROUND ART

A polishing composition containing abrasive grains is used for polishing, for example, a silicon substrate (see Patent document 1). In order to stabilize the quality of a polished product obtained by polishing an object, it is important to reduce aggregates in a polishing composition. In this regard, Patent document 2 discloses a technique of enhancing the dispersibility of abrasive grains. However, there is still a room to make further improvements to enhance the quality of a polished product.

### PRIOR ART DOCUMENTS

Patent document 1: Japanese National Phase Laid-Open Patent Publication No. 2005-518668
Patent document 2: Japanese Laid-Open Patent Publication No. 2001-15461

### SUMMARY OF THE INVENTION

### Problems that the Invention is to Solve

The present invention has been made by focusing attention on the generation of aggregates upon dilution of an undiluted liquid containing abrasive grains. It is an objective of the present invention to provide a polishing composition useful for producing a high-quality polished product, a method for producing the same, and an undiluted liquid. It is another objective of the present invention to provide a silicon substrate production method capable of easily obtaining a high-quality silicon substrate, and a high-quality silicon substrate.

### Means for Solving the Problems

In order to achieve the objectives described above and in accordance with one aspect of the present invention, provide is a polishing composition obtained through diluting an undiluted liquid containing abrasive grains, wherein when R1 is defined as an average secondary particle diameter of the abrasive grains in the undiluted liquid and R2 is defined as an average secondary particle diameter of the abrasive grains in the polishing composition, the ratio R2/R1 is 1.2 or less.

The undiluted liquid is preferably diluted at a dilution ratio of 2 times or more and 100 times or less.

The polishing composition is preferably obtained further through filtering a diluted liquid obtained by said diluting of the undiluted liquid.

A filter used in said filtering of the diluted liquid has an aperture of preferably 0.05 μm or more and 50 μm or less.

A filtration rate in said filtering of the diluted liquid is preferably 0.005 mL/(minute·mm²) or more and 10 mL/(minute·mm²) or less at a suction pressure of 50 kPa.

The polishing composition is preferably used for polishing a silicon substrate material.

In accordance with another aspect of the present invention, a method for producing a polishing composition is provided that includes diluting an undiluted liquid containing abrasive grains, wherein said diluting of the undiluted liquid is performed so that when R1 is defined as an average secondary particle diameter of the abrasive grains in the undiluted liquid and R2 is defined as an average secondary particle diameter of the abrasive grains in the polishing composition, the ratio R2/R1 is 1.2 or less.

In accordance with still another aspect of the present invention, a method for producing a silicon substrate is provided that includes polishing a silicon substrate material with the polishing composition.

In accordance with still another aspect of the present invention, a silicon substrate is provided that is obtained by polishing a silicon substrate material with the polishing composition.

In accordance with still another aspect of the present invention, provided is an undiluted liquid to be diluted 2 times or more and 100 times or less with water when used to prepare a polishing composition, wherein the undiluted liquid contains abrasive grains, and when R1 is defined as an average secondary particle diameter of the abrasive grains in the undiluted liquid and R2 is defined as an average secondary particle diameter of the abrasive grains in the polishing composition, the ratio R2/R1 is 1.2 or less.

### Effects of the Invention

The present invention succeeds in easily providing a high-quality polished product, such as a silicon substrate.

### MODES FOR CARRYING OUT THE INVENTION

Hereinafter, one embodiment of the present invention will be described.

A polishing composition according to the present embodiment is produced through a dilution step in which an undiluted liquid is diluted to obtain a diluted liquid and a filtering step in which the diluted liquid is filtered. The undiluted liquid contains abrasive grains and water.

When R1 is defined as an average secondary particle diameter of the abrasive grains in the undiluted liquid and R2 is defined as an average secondary particle diameter of the abrasive grains in the polishing composition, the ratio R2/R1 is 1.2 or less. The polishing composition of the present embodiment is used for polishing a silicon substrate material.

The abrasive grains function to mechanically polish a surface to be polished. Specific examples of the abrasive grains include particles made of a metal oxide, such as silica, alumina, ceria, zirconia, and titania; silicon carbide particles; calcium carbonate particles; and diamond particles. The abrasive grains may be used by one kind alone or in combination of two or more kinds.

The abrasive grains are preferably silica particles. Examples of the silica particles include colloidal silica and fumed silica. Among them, colloidal silica is preferable. When colloidal silica or fumed silica is used, particularly when colloidal silica is used, scratches to be formed on the surface of a silicon substrate by polishing with the polishing composition is reduced.

The average primary particle diameter of the abrasive grains is preferably 5 nm or more, more preferably 10 nm or more, and still more preferably 20 nm or more. As the average primary particle diameter of the abrasive grains increases, the polishing rate of a silicon substrate is improved.

The average primary particle diameter of the abrasive grains is also preferably 100 nm or less, more preferably 50 nm or less, and still more preferably 40 nm or less. As the average primary particle diameter of the abrasive grains decreases, the dispersion stability of the polishing composition is improved.

The average primary particle diameter of the abrasive grains is calculated, for example, from the specific surface area of the abrasive grains determined by the BET method. The specific surface area of the abrasive grains can be determined, for example, by using “Flow SorbII 2300”, manufactured by Micromeritics Instrument Corporation.

The content of the abrasive grains in the polishing composition is preferably 0.01% by mass or more. As the content of the abrasive grains increases, surface processing properties such as a polishing rate of the surface to be polished are improved.

The content of the abrasive grains in the polishing composition is also preferably 5% by mass or less, more preferably 1% by mass or less, and still more preferably 0.5% by mass or less. As the content of the abrasive grains decreases, the dispersion stability of the polishing composition is improved, and the residue of the abrasive grains on a polished surface tends to be reduced.

Water in the undiluted liquid serves as a dispersion medium or a solvent for other components in the undiluted liquid. For example, water in which the total content of transition metal ions is 100 ppb or less is preferably used in order to avoid as much as possible the actions of the other components from being inhibited. The purity of water can be enhanced by an operation such as removal of impurity ions using an ion-exchange resin, removal of foreign matters using a filter, and distillation. Specifically, ion-exchange water, pure water, ultrapure water, or distilled water is preferably used.

The pH of the polishing composition is preferably within the range of 8 to 12, and more preferably within the range of 9 to 11. When the pH of the polishing composition is within the range of 8 to 12, a preferable polishing rate is easily achieved in practice.

The undiluted liquid may further contain a water-soluble polymer or a basic compound, if needed.

The water-soluble polymer functions to enhance the wettability of a surface to be polished. A water-soluble polymer having at least one functional group selected from a cation group, an anion group, and a nonionic group in the molecule can be used. A water-soluble polymer to be used may contain a hydroxyl group, a carboxyl group, an acyloxy group, a sulfo group, a quaternary nitrogen structure, a heterocyclic structure, a vinyl structure, or a polyoxy alkylene structure in the molecule.

Specific examples of a water-soluble polymer include a cellulose derivative; an imine derivative, such as poly(N-acyl alkylene imine); polyvinyl alcohol; polyvinyl pyrrolidone; a copolymer containing polyvinyl pyrrolidone in a part of the structure; polyvinyl caprolactam; a copolymer containing polyvinyl caprolactam in a part of the structure; polyoxyethylene; a polymer having a polyoxy alkylene structure; a polymer having a multiple structure such as a diblock type, triblock type, random type, and alternate type thereof; and a polyether-modified silicone.

The water-soluble polymers may be used by one kind alone or in combination of two or more kinds.

A water-soluble polymer to be used is preferably a cellulose derivative, polyvinyl pyrrolidone, or a polymer having a polyoxy alkylene structure, since they have a good function of imparting hydrophilic properties. Specific examples of a cellulose derivative include hydroxyethyl cellulose, hydroxypropyl cellulose, hydroxyethylmethyl cellulose, hydroxypropylmethyl cellulose, methyl cellulose, ethyl cellulose, ethylhydroxyethyl cellulose, and carboxymethyl cellulose. Among the cellulose derivatives, hydroxyethyl cellulose is preferable from the viewpoints of having high ability to impart wettability to a polished surface and providing ease of washing off.

The weight average molecular weight of the water-soluble polymer is preferably 300 or more, more preferably 1,000 or more, still more preferably 10,000 or more, yet still more preferably 100,000 or more, and most preferably 200,000 or more, in terms of polyethylene oxide. As the weight average molecular weight of the water-soluble polymer increases, the hydrophilic properties of a surface to be polished tend to be enhanced.

The weight average molecular weight of the water-soluble polymer is also preferably less than 2,000,000, more preferably less than 1,500,000, still more preferably less than 1,000,000, and most preferably less than 500,000. As the weight average molecular weight of the water-soluble polymer decreases, the stability of the polishing composition is further improved.

The content of the water-soluble polymer in the polishing composition is preferably 0.002% by mass or more, more preferably 0.004% by mass or more, and still more preferably 0.006% by mass or more. As the content of the water-soluble polymer in the polishing composition increases, the wettability of a surface to be polished tends to be further enhanced.

The content of the water-soluble polymer in the polishing composition is also preferably 0.5% by mass or less, more preferably 0.2% by mass or less, and still more preferably 0.1% by mass or less. As the content of the water-soluble polymer in the polishing composition decreases, the dispersion stability of the polishing composition tends to be easily improved.

The basic compound functions to chemically polish a surface to be polished, and to improve the dispersion stability of the polishing composition.

Specific examples of a basic compound to be used include a hydroxide or salt of an alkali metal, a quaternary ammonium hydroxide or a salt thereof, ammonia, and an amine. Specific examples of an alkali metal include potassium and sodium. Specific examples of a salt include a carbonate, hydrogen carbonate, sulfate, and acetate. Specific examples of a quaternary ammonium include tetramethylammonium, tetraethylammonium, and tetrabutylammonium. Specific examples of a hydroxide or salt of an alkali metal include potassium hydroxide, potassium carbonate, potassium hydrogen carbonate, potassium sulfate, potassium acetate, and potassium chloride. Specific examples of a quaternary ammonium hydroxide or a salt thereof include tetramethylammonium hydroxide, tetraethylammonium hydroxide, and tetrabutylammonium hydroxide. Specific examples of an amine include methylamine, dimethylamine, trimethylamine, ethylamine, diethylamine, triethylamine, ethylenediamine, monoethanolamine, N-(β-aminoethyl)ethanolamine, hexamethylenediamine, diethylenetriamine, triethylenetetramine, anhydrous piperazine, piperazine hexahydrate, 1-(2-aminoethyl)piperazine, N-methylpiperazine, and guanidine. The basic compounds may be used by one kind alone or in combination of two or more kinds.

A basic compound to be used is preferably at least one selected from ammonia, an ammonium salt, an alkali metal hydroxide, an alkali metal salt, and a quaternary ammonium hydroxide. Among them, a basic compound to be used is preferably at least one selected from ammonia, potassium hydroxide, sodium hydroxide, tetramethylammonium hydroxide, tetraethylammonium hydroxide, ammonium hydrogen carbonate, ammonium carbonate, potassium hydrogen carbonate, potassium carbonate, sodium hydrogen carbonate, and sodium carbonate, more preferably at least one selected from ammonia, potassium hydroxide, sodium hydroxide, tetramethylammonium hydroxide, and tetraethylammonium hydroxide, still more preferably at least one of ammonia and tetramethylammonium hydroxide, and most preferably ammonia.

The content of the basic compound in the polishing composition is preferably 0.001% by mass or more, more preferably 0.002% by mass or more, and still more preferably 0.003% by mass or more. As the content of the basic compound in the polishing composition increases, the function of chemically polishing a surface to be polished, and the function of improving the dispersion stability of the polishing composition tend to be enhanced.

The content of the basic compound in the polishing composition is also preferably 1.0% by mass or less, more preferably 0.5% by mass or less, and still more preferably 0.2% by mass or less. As the content of the basic compound in the polishing composition decreases, the smoothness of a polished surface tends to be improved.

The undiluted liquid may further contain a surfactant, an organic acid, an organic acid salt, an inorganic acid, an inorganic acid salt, or a chelating agent, for example.

The surfactant functions to suppress the roughness of a polished surface. This easily reduces the haze level of the polished surface. Particularly, when the polishing composition contains a basic compound, roughness due to the chemical etching of the basic compound is likely to be caused on a polished surface, and therefore the use of a surfactant in combination with a basic compound is effective in suppressing the roughness.

The weight average molecular weight of a surfactant to be used may be less than 300. The surfactant may be an ionic surfactant or a nonionic surfactant, and among them, a nonionic surfactant is suitably used. Since a nonionic surfactant has low foamability, the handling of the polishing composition during preparation and use is facilitated. Also, the pH adjustment of the polishing composition when the nonionic surfactant is used is easier than that when the ionic surfactant is used.

Specific examples of a nonionic surfactant include oxyalkylene polymers, such as polyethylene glycol and polypropylene glycol; and polyoxyalkylene adducts, such as polyoxyethylene alkyl ether, polyoxyethylene alkyl phenyl ether, polyoxyethylene alkylamine, polyoxyethylene fatty acid ester, polyoxyethylene glycel ether fatty acid ester, and polyoxyethylene sorbitan fatty acid ester. More specific examples thereof include a polyoxyethylene polyoxypropylene copolymer, polyoxyethylene glycol, polyoxyethylene propyl ether, polyoxyethylene butyl ether, polyoxyethylene pentyl ether, polyoxyethylene hexyl ether, polyoxyethylene octyl ether, polyoxyethylene-2-ethylhexyl ether, polyoxyethylene nonyl ether, polyoxyethylene decyl ether, polyoxyethylene isodecyl ether, polyoxyethylene tridecyl ether, polyoxyethylene lauryl ether, polyoxyethylene cetyl ether, polyoxyethylene stearyl ether, polyoxyethylene isostearyl ether, polyoxyethylene oleyl ether, polyoxyethylene phenyl ether, polyoxyethylene octylphenyl ether, polyoxyethylene nonylphenyl ether, polyoxyethylene dodecylphenyl ether, polyoxyethylene styrenated phenyl ether, polyoxyethylene laurylamine, polyoxyethylene stearylamine, polyoxyethylene oleylamine, polyoxyethylene stearylamide, polyoxyethylene oleylamide, polyoxyethylene monolaurate ester, polyoxyethylene monostearate ester, polyoxyethylene distearate ester, polyoxyethylene monooleate ester, polyoxyethylene dioleate ester, polyoxyethylene sorbitan monolaurate, polyoxyethylene sorbitan monopalmitate, polyoxyethylene sorbitan monostearate, polyoxyethylene sorbitan monooleate, polyoxyethylene sorbitan trioleate, polyoxyethylene sorbitol tetraoleate, polyoxyethylene castor oil, and polyoxyethylene hydrogenated castor oil.

The surfactants may be used by one kind alone or in combination of two or more kinds.

The organic acid and the salt thereof, and the inorganic acid and the salt thereof function to improve the hydrophilic properties of a polished surface.

Specific examples of an organic acid to be used include fatty acids, such as formic acid, acetic acid, and propionic acid; aromatic carboxylic acids, such as benzoic acid and phthalic acid; citric acid; oxalic acid; tartaric acid; malic acid; maleic acid; fumaric acid; succinic acid; organic sulfonic acids; and organic phosphonic acids. Specific examples of an organic acid salt to be used include alkali metal salts, such as a sodium salt and potassium salt, of the organic acids, or ammonium salts thereof.

Specific examples of an inorganic acid to be used include sulfuric acid, nitric acid, hydrochloric acid, and carbonic acid. Specific examples of an inorganic acid salt to be used include alkali metal salts, such as a sodium salt and potassium salt, of the inorganic acids, or ammonium salts thereof.

Among the organic acid salts and the inorganic acid salts, an ammonium salt is preferable from the viewpoint of suppressing the metal contamination of a polished product.

The organic acids and the salts thereof, and the inorganic acids and the salts thereof may be used by one kind alone or in combination of two or more kinds.

The chelating agent functions to suppress the metal contamination of a polished product. Specific examples of a chelating agent to be used include an aminocarboxylic acid chelating agent and an organic phosphonic acid chelating agent. Specific examples of an aminocarboxylic acid chelating agent include ethylenediaminetetraacetic acid, sodium ethylenediaminetetraacetate, nitrilotriacetic acid, sodium nitrilotriacetate, ammonium nitrilotriacetate, hydroxyethyl ethylenediaminetriacetic acid, sodium hydroxyethyl ethylenediaminetriacetate, diethylenetriaminepentaacetic acid, sodium diethylenetriaminepentaacetate, triethylenetetraaminehexaacetic acid, and sodium triethylenetetraminehexaacetate. Specific examples of an organic phosphonic acid chelating agent include 2-aminoethylphosphonic acid, 1-hydroxyethylidene-1,1-diphosphonic acid, aminotri(methylenephosphonic acid), ethylenediaminetetrakis(methylenephosphonic acid), diethylenetriaminepenta(methylenephosphonic acid), ethane-1,1-diphosphonic acid, ethane-1,1,2-triphosphonic acid, ethane-1-hydroxy-1,1-diphosphonic acid, ethane-1-hydroxy-1,1,2-triphosphonic acid, ethane-1,2-dicarboxy-1,2-diphosphonic acid, methanehydroxy phosphonic acid, 2-phosphonobutane-1,2-dicarboxylic acid, 1-phosphonobutane-2,3,4-tricarboxylic acid, and α-methyl phosphonosuccinic acid.

A well-known mixing apparatus such as a blade-type stirrer, an ultrasonic disperser, and a homomixer can be used to mix the raw materials for the undiluted liquid. All the raw materials may be simultaneously mixed or may be mixed in no particular order.

The average secondary particle diameter R1 of the abrasive grains in the undiluted liquid is preferably 300 nm or less, more preferably 150 nm or less, and still more preferably 100 nm or less. As the average secondary particle diameter R1 decreases, the polishing precision of a surface to be polished is easily enhanced. The value of the average secondary particle diameter R1 can be determined by a dynamic light scattering method.

Water used for diluting the undiluted liquid in the dilution step may be any one previously described as water in the undiluted liquid. The undiluted liquid is preferably diluted by a method in which water is added gradually to the undiluted liquid while stirring the undiluted liquid in the mixing apparatus described above. Alternatively, after water is added to the undiluted liquid, stirring may be conducted using the mixing apparatus described above.

The dilution ratio D in the dilution step is preferably 2 times or more, more preferably 5 times or more, and still more preferably 10 times or more, in terms of volume. As the dilution ratio D increases, the transportation cost of the undiluted liquid can be reduced, and the space required for storing the undiluted liquid can be reduced.

The dilution ratio D in the dilution step is also preferably 100 times or less, more preferably 50 times or less, and still more preferably 30 times or less, in terms of volume. As the dilution ratio D decreases, the stability of the diluted liquid obtained by diluting the undiluted liquid and the stability of the polishing composition obtained by filtering the diluted liquid are easily secured.

The diluted liquid obtained by diluting the undiluted liquid in the dilution step is then subjected to the filtering step. The filtering step is performed for the purpose of removing aggregates of the abrasive grains contained in the diluted liquid. The filtration in the filtering step may be natural filtration, which is performed under the normal pressure, suction filtration, pressure filtration, or centrifugal filtration.

The filter used in the filtering step is preferably selected on the basis of the aperture. The aperture of the filter is preferably 0.05 μm or more, more preferably 0.1 μm or more. As the aperture of the filter increases, a practical filtration rate is easily obtained.

The aperture of the filter is preferably 50 μm or less, more preferably 5 μm or less, and still more preferably 0.3 μm or less. As the aperture of the filter decreases, a polishing composition useful for producing a high-quality silicon substrate is more easily obtained.

The aperture of the filter is announced as a nominal aperture by a filter maker.

The filtration rate in the filtering step is preferably 0.005 mL/(minute·mm²) or more, more preferably 0.010 mL/(minute·mm²) or more, and still more preferably 0.015 mL/(minute·mm²) or more, at a suction pressure of 50 kPa. As the filtration rate in the filtering step increases, the efficiency of the filtering step is improved.

The filtration rate in the filtering step is preferably 10 mL/(minute·mm²) or less, more preferably 8 mL/(minute·mm²) or less, and still more preferably 5 mL/(minute·mm²) or less, at a suction pressure of 50 kPa. As the filtration rate in the filtering step decreases, the removal efficiency of the foreign matters is enhanced, as a result of which a polishing composition useful for producing a high-quality silicon substrate is more easily obtained.

The filtration capacity of the filter, which is the amount of the undiluted liquid passing through the filter before the filter is clogged after the supply of the undiluted liquid to the filter is started, is preferably 0.1 mL/mm² or more, more preferably 0.2 mL/mm² or more, and still more preferably 0.3 mL/mm² or more. As the filtration capacity of the filter increases, the running cost of the filtering step can be reduced.

The filtration capacity of the filter is also preferably 10 mL/mm² or less, more preferably 8 mL/mm² or less, and still more preferably 5 mL/mm² or less. As the filtration capacity of the filter decreases, the removal efficiency of the foreign matters is enhanced, as a result of which the efficiency of the filtering step is improved.

The clogging of the filter as used herein refers to a state where the diluted liquid cannot be substantially filtered due to a large amount of foreign matters and aggregates caught on the filter, more specifically, a state where the filtration rate at a suction pressure of 50 kPa is 0.005 mL/(minute·mm²) or less.

The material of the filter is not particularly limited as long as the material is suitable for removing particles in a water-based solvent. Specific examples of the material of the filter include cellulose, nylon, polysulfone, polyether sulfone, polypropylene, polytetrafluoroethylene (PTFE), and polycarbonate. From the viewpoint of filtration precision, nylon, polypropylene, or polyether sulfone is preferable. Furthermore, when the viewpoint of a filter life is also considered, polypropylene is more preferable.

The filter may be a membrane filter or a depth filter. The shape of the filter is not particularly limited. For example, the shape may be of a flat membrane type, a pleated type, and a hollow fiber type.

The polishing composition is composed of a filtrate obtained in the filtering step, i.e., the filtered diluted liquid.

The ratio R2/R1 of the average secondary particle diameter R2 of the abrasive grains in the polishing composition to the average secondary particle diameter R1 of the abrasive grains in the undiluted liquid is 1.2 or less, preferably 1.15 or less, and more preferably 1.1 or less. As the ratio R2/R1 decreases, a polishing composition useful for producing a high-quality silicon substrate is easily obtained.

The ratio R2/R1 is also preferably 0.5 or more, more preferably 0.6 or more, and still more preferably 0.7 or more. As the ratio R2/R1 increases, a polishing composition having a practical polishing rate is easily obtained.

The value of the average secondary particle diameter R2 of the abrasive grains in the polishing composition can be measured by a dynamic light scattering method as in the average secondary particle diameter R1 in the undiluted liquid.

Next, a method for producing a silicon substrate using a polishing composition will be described with the action of the polishing composition.

The polishing composition can be used for a polishing step, such as lapping processing and polishing processing, using as an object to be polished a silicon substrate material cut out from a silicon ingot. Specifically, a polishing pad is pressed against a surface to be polished of the silicon substrate material while the polishing composition is supplied onto the surface, and the silicon substrate material and the polishing pad are rotated.

The amount of the aggregates contained in the undiluted liquid tends to be increased through the dilution step. When the polishing composition contains a larger amount of aggregates, the aggregates may cause the adverse effects to the silicon substrate material or the silicon substrate. In this regard, according to the polishing composition of the present embodiment, the ratio R2/R1 of the average secondary particle diameter R2 of the abrasive grains in the polishing composition to the average secondary particle diameter R1 of the abrasive grains in the undiluted liquid is 1.2 or less. That is, the aggregation of the abrasive grains generated through the dilution step is suppressed. Therefore, the silicon substrate material and the silicon substrate are less likely to be affected by the aggregates in the polishing composition.

A silicon substrate, which is a polished product, is obtained by rinsing the silicon substrate after the polishing step and then drying the silicon substrate.

The polishing composition of the present embodiment has a particularly-high utility value when the polishing composition contains the abrasive grains, the water-soluble polymer, and water and is used for the final polishing of the silicon substrate material. In the case of such a polishing composition, bridged aggregation among the abrasive grains in the polishing composition may be caused by the water-soluble polymer. The bridged aggregation is likely to be generated in the dilution step, in which the undiluted liquid is diluted with water. In many cases, the bridged aggregates generated in the dilution step remains without being re-dispersed in the polishing composition. When the bridged aggregates remain on the silicon substrate after the final polishing, surface defects referred to as light point defects (LPDs) may be caused. In this regard, since the aggregation of the abrasive grains in the polishing composition of the present embodiment is suppressed, the aggregates can be prevented from remaining on the silicon substrate after the final polishing.

When the polishing composition is used for the final polishing of the silicon substrate material, the number of coarse particles contained in the polishing composition and having a size of 0.7 μm or more is preferably as small as possible. Specifically, the number of the coarse particles of 0.7 μm or more contained in the polishing composition is preferably 4,000 or less per 1 mL, more preferably 2,000 or less per 1 mL, and still more preferably 1,500 or less per 1 mL. The number of the coarse particles in the polishing composition can be reduced by diluting the undiluted liquid and thereafter filtering the diluted liquid.

The present embodiment described in detail above exhibits the following effects.

(1) In the case of the polishing composition of the present embodiment, the ratio R2/R1 of the average secondary particle diameter R2 of the abrasive grains in the polishing composition to the average secondary particle diameter R1 of the abrasive grains in the undiluted liquid is 1.2 or less. That is, the aggregation of the abrasive grains generated through the dilution step is suppressed. Therefore, a polished product produced by using the polishing composition is less likely to be affected by the aggregates in the polishing composition. Therefore, a high-quality polished product is easily obtained.

(2) When the polishing composition is obtained by diluting the undiluted liquid 2 times or more and 100 times or less, the transportation cost of the undiluted liquid can be reduced, and the space required for storing the undiluted liquid can be reduced. Furthermore, the stabilities of the diluted liquid and polishing composition are easily secured.

(3) When the polishing composition is obtained by diluting the undiluted liquid and then filtering the diluted liquid, the ratio R2/R1 is easily set to 1.2 or less.

(4) When the filter used in the filtering step has an aperture of 0.05 μm or more and 50 μm or less, the practical filtration rate is easily obtained, and a polishing composition useful for producing a high-quality polished product is more easily obtained.

(5) When the filtration rate in the filtering step is 0.005 mL/(minute·mm²) or more and 10 mL/(minute·mm²) or less at a suction pressure of 50 kPa, the efficiency of the filtering step is improved, and a polishing composition useful for producing a high-quality polished product is more easily obtained.

(6) When the polishing composition of the present embodiment is used for polishing a silicon substrate material, a high-quality silicon substrate is easily obtained.

(7) Since the undiluted liquid is diluted so that the ratio R2/R1 of the average secondary particle diameter R2 of the abrasive grains in the polishing composition to the average secondary particle diameter R1 of the abrasive grains in the undiluted liquid is 1.2 or less according to the method for producing a polishing composition of the present embodiment, a polishing composition useful for producing a high-quality polished product can be obtained.

(8) According to the method for producing a silicon substrate that includes polishing a silicon substrate material with the polishing composition of the present embodiment, a high-quality silicon substrate can be easily obtained.

(9) The silicon substrate obtained by polishing a silicon substrate material with the polishing composition of the present embodiment has few LPDs caused by coarse particles, such as foreign matters and aggregates, in the polishing composition and has high quality.

(10) The polishing composition of the present embodiment is useful for producing a high-quality polished product as described in the item (1). Therefore, the undiluted liquid used to prepare the polishing composition is also said to be useful for producing a high-quality polished product.

The embodiments may be modified as follows.
The polishing composition may further contain a known additive such as a preservative agent and an antifungal agent, if needed. Specific examples of preservative agents and antifungal agents include isothiazoline compounds, para-oxybenzoates, and phenoxyethanol.
The method for producing a polishing composition may further include adding a raw material being less likely to contain foreign matters or a raw material being less likely to be aggregated to the diluted liquid obtained by diluting the undiluted liquid.
The filtering step in which the diluted liquid is filtered may be omitted.
The filtering step may be performed at one stage, or may be divided into and performed at plural stages. When the filtering step is divided into plural stages, the filters used in the stages may be the same. Alternatively, filters having different apertures or materials may be used at the stages. When filters having different apertures are used at the stages, the aperture of the filter to be used at the latter stage is preferably finer than that of the filter to be used at the former stage.
The filtering step may be performed by batch filtration, or may be performed by circulating filtration.
The method for producing a polishing composition may further include the step of filtering the undiluted liquid, or the step of filtering the raw materials for the polishing composition before preparing the undiluted liquid.
The abrasive grains may have a spherical shape or a non-spherical shape, such as a peanut shell shape having a constricted central portion, a spiky shape having a surface with projections, and a rugby ball shape.
The polishing pad used in polishing using the polishing composition is not particularly limited. The polishing pad may be of a nonwoven type or a suede type. The polishing pad may contain abrasive grains or may not contain abrasive grains.
The polishing composition may be of a one-pack type, or may be of a multi-pack type including two or more packs.
The polishing composition may be used to produce a polished product other than a silicon substrate, for example, a silicon oxide substrate, a plastic substrate, a glass substrate, and a quartz substrate. Since the aggregates contained in the polishing composition are few, a high-quality polished product is easily obtained also in such a case. The raw materials for the polishing composition may be appropriately changed depending on a polished product to be produced by using the polishing composition. For example, the raw materials may contain resin particles as abrasive grains.

The following is a technical idea capable of being grasped from the embodiments and modification described above.

A method for preparing a polishing composition, comprising:

diluting an undiluted liquid containing abrasive grains to obtain a diluted liquid; and

filtering the diluted liquid,

wherein when R1 is defined as an average secondary particle diameter of the abrasive grains in the undiluted liquid and R2 is defined as an average secondary particle diameter of the abrasive grains in the polishing composition, a ratio R2/R1 is reduced by said filtering of the diluted liquid.

### Examples

Next, the present invention will be more specifically described with reference to examples and comparative examples.

Colloidal silica, a water-soluble polymer, a basic compound, and an organic acid salt were mixed with ion-exchange water to prepare undiluted liquids of Examples 1 to 4 and Comparative Example 1. The components of each undiluted liquid are shown in Table 1.

The average particle diameter of the used colloidal silica was measured by a dynamic light scattering method using UPA-UT151, manufactured by Nikkiso Co., Ltd. The values of the measured average particle diameters are shown in the “particle diameter” column in the “colloidal silica” column of Table 1.

“HEC” in the “water-soluble polymer” column of Table 1 represents hydroxyethyl cellulose. “PVP” represents polyvinyl pyrrolidone. “A1” represents a polyethylene oxide-polypropylene oxide-polyethylene oxide (PEO-PPO-PEO) triblock copolymer. “B1” in the “organic acid salt” column of Table 1 represents triammonium citrate.

The average secondary particle diameter R1 of the silica particles in each of the undiluted liquids was measured by a dynamic light scattering method using FPAR-100, manufactured by Otsuka Electronics Co., Ltd. The results are shown in the “R1” column of Table 2.

Each of the undiluted liquids was diluted 20 times in volume with pure water while stirring using a homogenizer to obtain a diluted liquid. The diluted liquids were then filtered to prepare polishing compositions of Example 1 to 4 and Comparative Example 1. The diluted liquid was filtered under the conditions described in Table 3 by using a filter having an aperture with a size described in the “aperture” column of Table 2. As a result, filtration rates having values described in the “filtration rate” column of Table 2 were obtained. The polishing compositions of Example 4 and Comparative Example 1 were prepared without filtering the diluted liquid.

The average secondary particle diameter R2 of the silica particles in each of the polishing compositions was measured by a dynamic light scattering method using FPAR-100, manufactured by Otsuka Electronics Co., Ltd. The results are shown in the “R2” column of Table 2. The ratio of the average secondary particle diameter R2 to the average secondary particle diameter R1 is shown in the “R2/R1” column of Table 2.

The number of coarse particles contained in each polishing composition and having a size of 0.7 μm or more was measured. The number was measured by using AccuSizerFX, manufactured by Particle Sizing Systems. The results are shown in the “LPC (Large Particle Count)” column of Table 2.

The surface of silicon substrate material was polished under the conditions described in Table 4 with each of the polishing compositions. The silicon substrate materials used had a diameter of 300 mm, p-type conduction, a crystal orientation of <100>, and a resistivity of 0.1 Ω·cm or more and less than 100 Ω·cm. The silicon substrate materials were preliminarily polished with a polishing slurry (trade name: GLANZOX 1103) manufactured by Fujimi Incorporated. The number of particles existing on the surface of each of the polished silicon substrates and having a size of 37 nm or more was measured by using wafer inspection equipment Surfscan SP2, manufactured by KLA-Tencor Corporation. The results are shown in the “particles” column of Table 2.

The polishing composition of Example 1 was subjected to suction filtration at a filtration pressure difference of 5 kPa by using each of disc filters having materials and structures described in the “filter material” column and “filter structure” column of Table 5, and having a diameter of 47 mm and an aperture of 0.45 μm. When the amount of the polishing composition passing through each filter before the filter was clogged after the suction filtration was started was more than 2 L, the filter life was evaluated as A. When the amount was 2 L or less, the filter life was evaluated as B. Results are shown in the “filter life” column of Table 5. The number of coarse particles contained in the filtrate obtained as a result of the suction filtration using each filter and having a size of 0.7 μm or more was measured by using AccuSizerFX, manufactured by Particle Sizing Systems. When the number of the coarse particles was less than 200 particles/mL, the filtration precision was evaluated as A. When the number was 200 particles/mL or more, the filtration precision was evaluated as B. Results are shown in the “filtration precision” column of Table 5.

TABLE 1

| | | | Water-soluble polymer | | | | | | |
|---|---|---|---|---|---|---|---|---|---|
| | Colloidal silica | | | Weight | | Basic compound | | Organic acid salt | |
| | Particle | Content | | average | Content | | Content | | Content |
| | diameter | [% by | | molecular | [% by | | [% by | | [% by |
| | [nm] | mass] | Kind | weight | mass] | Kind | mass] | Kind | mass] |
| Example 1 | 65 | 9 | HEC | 250000 | 0.3 | Ammonia | 0.2 | B1 | 0.2 |
| | | | PVP | 45000 | 0.17 | | | | |
| | | | A1 | 9000 | 0.01 | | | | |
| Example 2 | 65 | 9 | HEC | 250000 | 0.3 | Ammonia | 0.2 | B1 | 0.1 |
| | | | PVP | 45000 | 0.04 | | | | |
| | | | A1 | 9000 | 0.05 | | | | |

| | | | | | | | | |
|---|---|---|---|---|---|---|---|---|
| Example 3 | 65 | 9 | HEC | 250000 | 0.3 | Ammonia | 0.2 | — |
| | | | A1 | 9000 | 0.05 | | | |
| Example 4 | 65 | 9 | HEC | 250000 | 0.3 | Ammonia | 0.2 | — |
| | | | A1 | 9000 | 0.05 | | | |
| Comparative | 65 | 9 | HEC | 250000 | 0.3 | Ammonia | 0.2 | — |
| Example 1 | | | | | | | | |

TABLE 2

| | | | Filtering step | | | | | |
|---|---|---|---|---|---|---|---|---|
| | R1 | Dilution | Aperture | Filtration rate | R2 | | LPC | |
| | [nm] | ratio D | [μm] | [mL/(minute · mm²)] | [nm] | R2/R1 | [#/mL] | Particles |
| Example 1 | 81 | 20 times | 1.0 | 0.38 | 89 | 1.10 | 419 | 52 |
| Example 2 | 85 | 20 times | 1.0 | 0.32 | 96 | 1.13 | 1412 | 65 |
| Example 3 | 90 | 20 times | 1.0 | 0.18 | 106 | 1.17 | 1446 | 79 |
| Example 4 | 90 | 20 times | — | — | 108 | 1.20 | 2830 | 130 |
| Comparative | 97 | 20 times | — | — | 122 | 1.26 | 8640 | 288 |
| Example 1 | | | | | | | | |

TABLE 3

| Filtration method: | Suction filtration | |
|---|---|---|
| Suction pressure: | 50 | kPa |
| Filtration time: | 5 | minutes |
| Type of filter: | Cellulose mixed ester-type membrane filter | |
| | manufactured by Toyo Roshi Kaisha, Ltd. | |
| filter diameter: | 47 | mm |

TABLE 4

| Polishing machine: | Single wafer polishing machine (PNX-332B, | |
|---|---|---|
| | manufactured by Okamoto Machine Tool | |
| | Works, Ltd.) | |
| Polishing load: | 15 | kPa |
| Rotation speed of platen: | 30 | rpm |
| Rotation speed of head: | 30 | rpm |
| Polishing time: | 4 | minutes |
| Temperature of polishing | 20 | ° C. |
| composition: | | |

| | |
|---|---|
| Feeding rate of polishing | 0.5 L/minute (continuously fed without |
| composition: | being circulated) |

TABLE 5

| | | Filter | Filtration |
|---|---|---|---|
| Filter material | Filter structure | life | precision |
| Nylon 66 | Single-layer porous | B | A |
| Polypropylene | Multilayered nonwoven | A | A |
| Polyether sulfone | Single-layer porous | B | A |
| Cellulose mixed ester | Single-layer porous | B | B |
| Cellulose acetate | Single-layer porous | B | B |

As shown in Table 2, the polishing compositions of Examples 1 to 4 had LPC measurement values lower than that of the polishing composition of Comparative Example 1. Furthermore, the measurement values of particles when the polishing compositions of Examples 1 to 4 were used were lower than that obtained when the polishing composition of Comparative Example 1 was used. From these results, the polishing composition for which the ratio R2/R1 is 1.2 or less is found to be useful for producing a high-quality polished product on which the coarse particles in the polishing composition are less likely to remain.

1. A polishing composition obtained through diluting an undiluted liquid containing abrasive grains,
wherein when R1 is defined as an average secondary particle diameter of the abrasive grains in the undiluted liquid and R2 is defined as an average secondary particle diameter of the abrasive grains in the polishing composition, a ratio R2/R1 is 1.2 or less.

2. The polishing composition according to claim 1, wherein the undiluted liquid is diluted at a dilution ratio of 2 times or more and 100 times or less.

3. The polishing composition according to claim 1, wherein the polishing composition is obtained further through filtering a diluted liquid obtained by said diluting of the undiluted liquid.

4. The polishing composition according to claim 3, wherein a filter used in said filtering of the diluted liquid has an aperture of 0.05 μm or more and 50 μm or less.

5. The polishing composition according to claim 3, wherein a filtration rate in said filtering of the diluted liquid is 0.005 mL/(minute·mm²) or more and 10 mL/(minute·mm²) or less at a suction pressure of 50 kPa.

6. The polishing composition according to claim 1, wherein the polishing composition is used for polishing a silicon substrate material.

7. A method for producing a polishing composition, comprising diluting an undiluted liquid containing abrasive grains,
wherein said diluting of the undiluted liquid is performed so that when R1 is defined as an average secondary particle diameter of the abrasive grains in the undiluted liquid and R2 is defined as an average secondary particle diameter of the abrasive grains in the polishing composition, a ratio R2/R1 is 1.2 or less.

8. A method for producing a silicon substrate, comprising polishing a silicon substrate material with the polishing composition according to claim 1.

9. A silicon substrate obtained by polishing a silicon substrate material with the polishing composition according to claim 1.

10. An undiluted liquid to be diluted 2 times or more and 100 times or less with water when used to prepare a polishing composition, wherein
the undiluted liquid contains abrasive grains, and
when R1 is defined as an average secondary particle diameter of the abrasive grains in the undiluted liquid and R2 is defined as an average secondary particle diameter of the abrasive grains in the polishing composition, a ratio R2/R1 is 1.2 or less.
